(19) United States
(12) Patent Application Publication
(10) Pub. No.: US 2010/0166536 A1
(43) Pub. Date: Jul. 1, 2010

(54) Apparatus for the separating of stacked plate-shaped elements

(76) Inventors: Lothar Andritzke, Mueglitztal (DE); Ulrich Goedicke, Dresden (DE); Juergen Doepping, Freiberg (DE); Lars Esser, Chemnitz (DE)

Correspondence Address: JACOBSON HOLMAN PLLC, 400 SEVENTH STREET N.W., SUITE 600, WASHINGTON, DC, 20004, US

(21) Appl. No.: 12/654,045

(22) Filed: Dec. 8, 2009

(30) Foreign Application Priority Data
Dec. 19, 2008 (DE) 10 2008 064 555.9
Mar. 11, 2009 (DE) 10 2009 013 958.3

(51) Int. Cl. B65G 59/02; H01L 21/677

(52) U.S. Cl. 414/795.7; 414/796.7

(57) ABSTRACT

The invention relates to an apparatus for the separating of stacked plate-shaped elements. It is the object of the invention to provide possibilities with which stacked plate-shaped elements, in particular plate-shaped elements prone to breakage, can be reliably separated in a short time and to increase the useful operating time of an apparatus. In the invention, a stack of plate-shaped elements is placed onto a lifting device with which a stepped raising in vertical stages takes place. A conveying device for plate-shaped elements is arranged above the stack, with at least one conveying element being fastened to a conveyor belt made in the form of a continuous conveyor or to at least one rotating roller at said conveying device. Conveying elements are made from an elastically deformable material and have at least one end face in the direction of the surfaces of plate-shaped elements to be separated.

Conveying elements are dimensioned and are arranged at a spacing from the surface of a plate-shaped element arranged vertically upward at a stack such that conveying elements are brought into a mechanical contact with the surface of the plate-shaped element arranged vertically upward in the stack on a translatory movement of the conveyor belt or on a rotation of the rollers and a force is thereby exerted onto the surface of this plate-shaped element and this plate-shaped element can be moved from the stack by the movement of the conveying elements in the conveying direction.

The invention relates to an apparatus for the separating of stacked plate-shaped elements. Very fragile plate-shaped elements which are prone to breakage, such as silicon wafers, can in particular be handled using the apparatus in accordance with the invention.

Silicon wafers are manufactured from parallelepiped blocks by lapping with a cutting wire. Despite a pre-cleaning which is usually carried out, residues of a lapping suspension remain at the surfaces of the individual sawn wafers. This further increases the adhesive forces anyway acting between the stacked wafers. In this respect, depending on the quantity of the lapping suspension still present between wafers, adhesive forces of different orders of magnitude are active, which is particularly problematic for a separation of the wafers from a stack. Vacuum grippers or apparatus utilizing similar principles can thus, for example, not be used, or can only be used while accepting a high reject rate.

An apparatus is thus known from DE 10 2005 016 519 B3 for separating, individualizing and transporting break sensitive substrates, such as also the wafers in question, arranged sequentially in a holding device.

The wafers aligned at an oblique angle are in this respect removed from the stack by means of a removal unit and are so separated. The removal unit has a stripping element and a driver. In this respect, a front wafer is pushed vertically obliquely upwardly by the driver. This takes place so long until a sufficiently large surface no longer has any contact to the wafer arranged next to it. The displaced wafer should now tilt over the upper edge of the wafer arranged next to it so that the rest of its surface also no longer has any contact to the adjacent wafer. The wafer separated in this manner can then slide off onto a conveying device.

Since, however, the silicon wafers are extremely prone to breakage, it is proposed in this prior art that the apparatus should be operated within a fluid. However, this is extremely disadvantageous since all moving parts or elements of the apparatus are exposed to the fluid and a correspondingly high sealing effort is required. In addition, the fluid is enriched with part of the lapping suspension during operation, which requires an increased cleaning effort and short service intervals and nevertheless decreases the service life of at least wear parts.

It is therefore the object of the invention to provide possibilities with which stacked plate-shaped elements, in particular plate-shaped elements prone to breakage, can be reliably separated in a short time and to increase the useful operating time of an apparatus.

This object is solved in accordance with the invention by an apparatus having the features of claim 1. Advantageous embodiments and further developments of the invention can be realized with technical features designed in dependent claims.

In an apparatus in accordance with the invention for the separating of stacked plate-shaped elements, said elements are stacked above one another. Such a stack can be placed on a lifting device. A stepped raising in vertical stages is possible using the lifting device.

A conveying device for plate-shaped elements is arranged vertically above the stack of plate-shaped elements. In an alternative in accordance with the invention, at least one conveying element at a conveying belt is present at a conveying device which is made in the form of a continuous conveyor.

In a second alternative in accordance with the invention, at least one conveying element can be attached radially outwardly to at least one rotating roller or drum and is moved along on the rotation. The axis of rotation should be aligned in a parallel plane to a further conveying device, which is arranged downstream, and at least approximately perpendicular to the conveying direction of said conveying device.

If more than one conveying element is present in both alternatives, they should be arranged at a spacing from one another. A plurality of conveying elements should be aligned parallel to one another and be fastened to the conveyor belt or to at least one roller. They are preferably replaceably attached. The number of conveying elements can be larger than two. In this respect, the length of plate-shaped elements can be taken into account in the conveying direction so that a plurality of conveying elements can also be used for plate-shaped elements longer in this direction.

The conveying elements are formed from an elastically deformable material, preferably from an elastomer. The conveying elements have at least one end face in the direction of the surfaces of plate-shaped elements to be separated. They are dimensioned and are arranged at a spacing from the surface of a plate-shaped element arranged vertically upwardly at a stack of plate-shaped elements such that they can be brought into a mechanical contact with the surface of the plate-shaped element arranged vertically upwardly in the stack on a translatory movement of the conveyor belt or on the rotation of at least one roller. A force is thereby exerted onto the surface of this plate-shaped element and this plate-shaped element can be moved from the stack in the conveying direction by the frictional force which is active by means of the translatory movement of the conveyor belt or by means of the rotational movement of at least one roller and of the conveying elements. It is thereby displaced from the stack of plate-shaped elements in the conveying direction.

An abutment is arranged beside the stack of plate-shaped elements in the conveying direction. The vertically upper end face edge of the abutment should be aligned parallel to the stacked plate-shaped elements. This end-face edge should moreover be arranged at a height which makes is possible that a movement of at least one plate-shaped element, which is arranged directly beneath the vertically upwardly arranged plate-shaped element, is prevented in the conveying direction. This can be necessary since this plate-shaped element has a tendency to move along as a result of the adhesive forces between the moving plate-shaped element disposed vertically above it. However, since it runs against the abutment, it can be prevented from its further movement by the abutment. This has the result that plate-shaped elements arranged beneath it are also prevented from moving.

The lifting device with which a stack of plate-shaped elements can be raised is made and can be operated in a controlled manner such that it can raise the stack with plate-shaped elements in vertical stages. A simultaneous double or multiple conveying of two or more plate-shaped elements from the stack can thus be avoided.

A further conveying device for a translatory transport of separated plate-shaped elements can be arranged behind the lifting device and the abutment in the conveying direction and can likewise be made as a continuous conveyor. This can likewise be a conveyor belt on which plate-shaped elements placed on in this manner can be transported for further processing. A plurality of conveyor belts, e.g. two conveyor belts can also be used in this respect which are driven together in the conveying direction and are arranged parallel next to one another.

A plurality of sets of conveying elements can be attached to the conveyor belt or to at least one roller at the conveying device for the displacement of the single plate-shaped elements. In this respect, one plate-shaped element can be pushed from the stack for separation with each set of conveying elements.

The stack and the conveyor belt or the roller should be arranged with respect to one another such that a conveying element or, with a set having more than one conveying element, the conveying element at the front in the conveying direction comes into mechanical contact behind the center of a plate-shaped element on the translatory movement of the conveyor belt. The respective plate-shaped element is thereby pulled on the separation and the force application required for this purpose takes place behind the center of mass of a plate-shaped element in the conveying direction.

At least one sensitive element, e.g. a sensor, which should be arranged above the stack of plate-shaped elements, should be present at an apparatus in accordance with the invention. The presence of plate-shaped elements on a lifting device can be recognized by said sensitive element. It can also be detected using preferably at least one sensor whether a plate-shaped element has been displaced from the stack for separation wholly, partly, or even in damaged form.

A stack of plate-shaped elements can be inserted into a magazine before the separation using an apparatus in accordance with the invention and the plate-shaped elements received in said magazine can be separated by a displacement and can then be transported onward for further processing. A magazine filled in this manner can be placed onto the lifting device with the stack of plate-shaped elements. A magazine should be open at least vertically upwardly.

A separation of stacked plate-shaped elements from above is possible with the invention. In this respect, they remain aligned substantially horizontally on the separation and on a subsequent transport onward, which is particularly gentle, and damage or breakage can thereby be avoided. In addition, a fluid bath in which the separation can be carried out can be dispensed with.

The invention should be explained in more detail by way of example in the following.

There are shown:

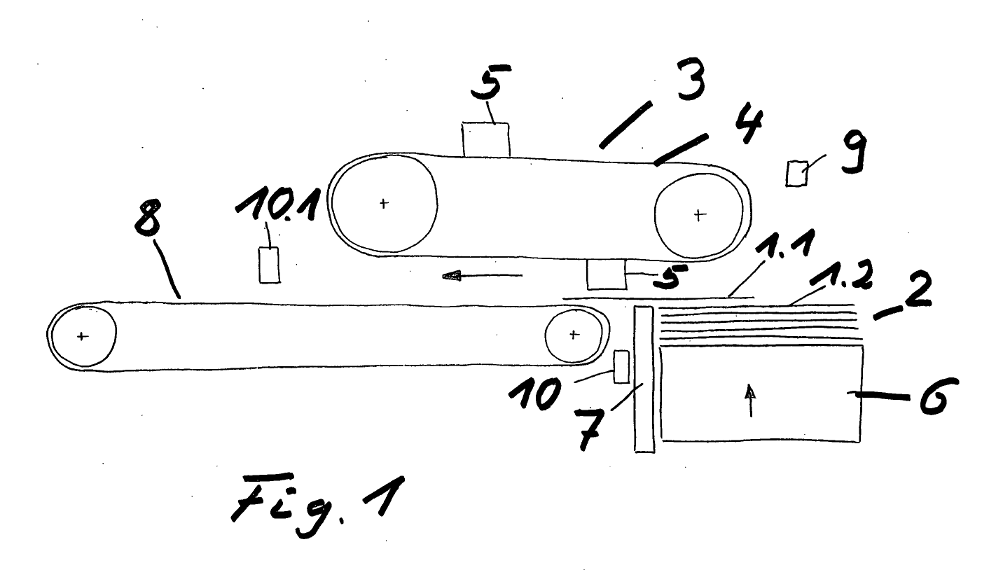

FIG. 1 major parts of an example of an apparatus in accordance with the invention in a schematic representation;

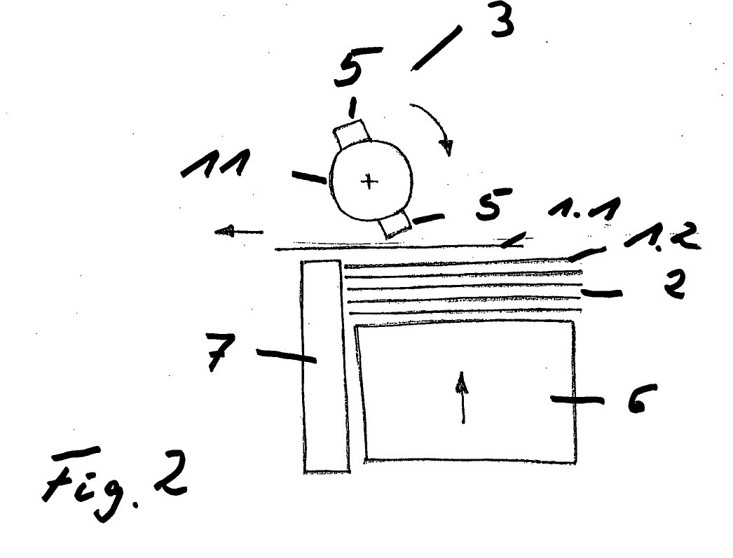

FIG. 2 a further example of an apparatus in accordance with the invention with a roller to which conveying elements are fastened; and

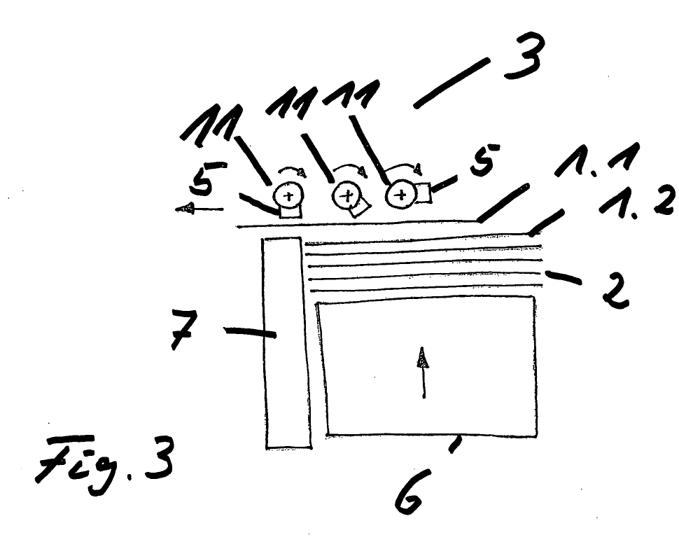

FIG. 3 a third example with a plurality of rollers.

Major elements of an example of an apparatus in accordance with the invention are shown in FIG. 1.

In this respect, silicon wafers are stacked above one another in a stack 2 as plate-shaped elements 1.1, 1.2, . . . . The stack 2 with the plate-shaped elements 1.2, 1.2, . . . is placed onto a lifting device 6 with which it can be raised in a stepped manner.

A conveying device 3 is arranged above the stack 2. Two conveying elements 5 are present at a conveyor belt 4 at the conveying device. The conveying elements 5 are made from an elastomer and are aligned perpendicular to the conveying direction which is marked by an arrow. The spacing of the conveyor belt 4 and the length of the conveying elements 5 have been selected so that the conveying elements 5 contact a vertically topmost plate-shaped element 1.1 on their path in the conveying direction and in so doing exert a force thereon from above. The stiction and the adhesive forces between the topmost plate-shaped element 1.1 and the plate-shaped element 1.2 arranged directly below it can thereby be overcome so that the topmost plate-shaped element 1.1 can be displaced in the conveying direction. It is thus transported to a further conveying device 8 and is supplied to subsequent processing by it. For reasons of better recognizability, the conveying elements 5 are shown smaller and do not contact the surfaces of the plate-shaped elements 1.1, 1.2, . . . in FIG. 1, which is, however, the case with the final technical embodiment of an apparatus in accordance with the invention.

An abutment 7 is attached directly next to the stack 2 in the conveying direction and the topmost plate-shaped element 1.1 can be displaced via its vertically upward end face edge when the lifting device 6 has moved the magazine with the plate-shaped elements 1.1, 1.2, . . . to the correct height. The plate-shaped element 1.2 arranged directly below it is thus prevented from moving along in the conveying direction since it abuts the abutment 7.

If the topmost plate-shaped element 1.1 has been displaced so far that it has been separated from the stack 2 of plate-shaped elements 1.1, 1.2, . . . , the lifting device 6 raises the stack 2 to the next height stage so that the procedure can be repeated for the separation of the plate-shaped element 1.2 which is now the topmost plate-shaped element. In this respect, the conveyor belt 4 has been moved onward so that this can take place with the conveying element 5 which is arranged upwardly in FIG. 1.

In addition, at least one sensor 9, with which plate-shaped elements 1.1, 1.2, . . . , can be detected, preferably optically, is present above the stack 2 which is arranged at the lifting device 6. This relates to the presence of plate-shaped elements 1.1, 1.2, . . . on the lifting device 6.

It can be detected with a further sensor 10 whether a topmost plate-shaped element 1.1 has actually been removed from the stack 2 without damage by the conveying element(s) 5 of the conveying device 3. If it is detected that a topmost plate-shaped element 1.1 has not been removed or has only partly been removed from the stack 2, the lifting device 6 is not activated, the stack 2 is left at the same height and the procedure is repeated so often until a successful removal has been achieved and the plate-shaped element 1.2 arranged below up to this point is then the topmost plate-shaped element and can then, after the raising of the stack 2 into the next following height stage by the lifting device 6 be removed from said stack and can next be supplied to the conveying device 8 by means of the conveying device 3.

In this example, a further sensor 10.1 is present with which the movement on the transport of plate-shaped elements 1.1, 1.2, . . . , and optionally their state, can be monitored. The sensor is here arranged in the direction of the end of the conveying device 8 and above it.

An apparatus in accordance with the invention can, as shown in FIGS. 2 and 3, however, also be made such that a conveying device 3 is used without a conveyor belt 4. In this respect, at least one conveying element 5 can be present radially outwardly at a rotating roller 11. In this case, the radius of a roller 11 can also be taken in to account in the dimensioning, in addition to the respective size of conveying elements 5 and the spacing from a vertically upper plate-shaped element 1.1 to be separated, since the respective path on which a conveying element 5 and a plate-shaped element 1.1. to be moved from the stack 2 touch mechanically can also be influenced by said radius. In the example in accordance with FIG. 2, two conveying elements 5 are fastened to a rotating roller 11 offset by 180° with respect to one another. On the rotation of the roller 11, a respective vertically topmost plate-shaped element 1.1 can be moved from the stack 2 in an analog manner to the example of FIG. 1.

In the example shown in FIG. 3, a conveying device 3 is shown having three rollers 11 to each of which a respective conveying element 5 is fastened. The rollers 11 have the same outer diameters and the axes of rotation are arranged in a plane above the stack 2. The conveying elements 5 have the same dimensions and the same design here. With the same direction of rotation, the conveying elements 5 can, however, be arranged at the periphery of the rollers 11 such they come successively into mechanical contact with the respective vertically topmost plate-shaped element 1.1 to move it from the stack 2.

1. An apparatus for the separating of stacked plate-shaped elements, wherein a stack (2) of plate-shaped elements can be placed onto a lifting device (6) with which a stepped raising in vertical states takes place; and
a conveying device (3) for plate shaped elements (1.1, 1.2, . . . ) is arranged vertically above the stack (2), with at least one conveying element (5) being fastened to a conveyor belt (4) made in the form of a continuous conveyor or to at least one rotating roller (11);
wherein the conveying element(s) (5) is/are made from an elastically deformable material and has/have at least one end face in the direction of the surfaces of plate-shaped elements (1.1, 1.2, . . . ) to be separated; and
the conveying element(s) (5) are dimensioned and are arranged at a spacing from the surface of a plate-shaped element (1.1) arranged vertically upward at a stack (2) of plate-shaped elements (1.1, 1.2, . . . ) such that the conveying element(s) (5) can be brought into a mechanical contact with the surface of the plate-shaped element (1.1) arranged vertically upward in the stack (2) on a translatory movement of the conveyor belt (4) or on a rotation of the roller(s) (11) and a force is thereby exerted onto the surface of this plate-shaped element (1,1) and this plate-shaped element (1.1) can be moved from the stack by the movement of the conveying element(s) (5) in the conveying direction.

2. An apparatus in accordance with claim 1, characterized in that an abutment (7) is arranged beside the stack (2) of plate-shaped elements (1.1, 1.2, . . . ) in the conveying direction, with the vertically upper end face edge of said abutment being aligned parallel to the stacked plate-shaped elements (1.1, 1.2, . . . ) and with this end face edge being arranged at a height such that it prevents a movement of at least one plate-shaped element (1.2) in the conveying direction which is arranged directly below the vertically upwardly arranged plate-shaped element (1.1).

3. An apparatus in accordance with claim 1, characterized in that the conveying element(s) (5) is/are made from an elastomer.

4. An apparatus in accordance with claim 1, characterized in that a further conveying device (8) for a translatory transport of separated plate-shaped elements (1.1, 1.2, . . . ) is arranged behind the lifting device (6) and the abutment (7) in the conveying direction.

5. An apparatus in accordance with claim 1, characterized in that at least one set of conveying elements (5) is fastened to the conveyor belt (4) or to the roller(s) (11).

6. An apparatus in accordance with claim 1, characterized in that at least one sensitive element (9) for a detection of the presence of plate-shaped elements (1.1, 1.2, . . . ) is arranged vertically above the stack (2) of plate-shaped elements (1.1, 1.2, . . . ).

7. An apparatus in accordance with claim 1, characterized in that at least one sensor (10) for a detection of the movement of plate-shaped elements (1.1, 1.2, . . . , ) is arranged next to the stack (2) in the conveying direction.

8. An apparatus in accordance with claim 1, characterized in that the stack (2) and the conveyor belt (4) or the roller(s) (11) are arranged with respect to one another such that, on a translatory movement of the conveyor belt (4) or on a rotation of the roller(s) (11), a single conveying element (5) fastened thereto or a conveying element (5) at the front in the conveying direction comes into mechanical contact with the plate-shaped element (1.1) behind the center of a plate-shaped element (1.1).

9. An apparatus in accordance with claim 1, characterized in that a stack (2) of plate-shaped elements (1.1, 1.2, . . . , ) is received in a magazine.

10. An apparatus in accordance with claim 1, characterized in that the plate-shaped elements (1.1, 1.2, . . . ) are silicon wafers.
